(19) United States
(12) Patent Application Publication
(10) Pub. No.: US 2019/0222193 A1
(43) Pub. Date: Jul. 18, 2019

(54) Bulk Acoustic Wave Resonator having a Lateral Energy Barrier

(71) Applicant: Snaptrack, Inc., San Diego, CA (US)

(72) Inventors: Bernhard BADER, Munich (DE); Andreas TAG, Munich (DE); Maximilian SCHIEK, Munich (DE)

(21) Appl. No.: 15/873,780

(22) Filed: Jan. 17, 2018

(51) Int. Cl. H03H 9/02; H03H 9/17

(52) U.S. Cl. CPC H03H 9/02866; H03H 9/02118; H03H 9/02015; H03H 9/175

(57) ABSTRACT

Bulk acoustic wave resonators having a lateral energy barrier are disclosed. In an example aspect, a resonator includes a volume of piezoelectric material, a bottom electrode, a top electrode, and a reflector. The bottom electrode is disposed below a portion of a lower surface of the volume of piezoelectric material. The top electrode is disposed above a portion of an upper surface of the volume of piezoelectric material with a portion of the top electrode overlapping a portion of the bottom electrode to define an active region of the volume of piezoelectric material configured to resonate acoustic waves having frequencies within a specified passband. The reflector is disposed on an upper surface of the volume of piezoelectric material outside of the active region with the reflector configured as a lateral energy barrier to reflect laterally propagating acoustic waves having frequencies within the specified passband.

### TECHNICAL FIELD

This disclosure relates generally to acoustic resonators and, more specifically, bulk acoustic wave resonators.

### BACKGROUND

Acoustic resonators can be used for filtering high-frequency signal waves. Using a volume of piezoelectric material as a vibrating medium, acoustic resonators operate by transforming an electrical signal wave that is propagating along an electrical conductor into an acoustic signal wave that is propagating via the volume of piezoelectric material. The acoustic signal wave propagates at a velocity having a magnitude that is significantly less than that of the propagation velocity of the electrical signal wave. Generally, the magnitude of the propagation velocity of a signal wave is proportional to a size of a wavelength of the signal wave. Consequently, after conversion of an electrical signal into an acoustic signal, the wavelength of the acoustic signal wave is significantly smaller than the wavelength of the electrical signal. The resulting smaller wavelength of the acoustic signal enables filtering to be performed using a smaller filter device (“acoustic filter”), which can include one or more acoustic resonators. This permits acoustic resonators to be used in electronic devices having size constraints, such as cellular phones and smart watches.

Bulk acoustic wave (also called “BAW” or “volume”) resonators are a type of acoustic resonators manufactured in a sandwich construction. The sandwich construction includes a volume of piezoelectric material positioned between an overlap of two electrodes defining an active region of the BAW resonator. One of the two electrodes is coupled to a terminal to provide an input signal for filtering. The other of the two electrodes is coupled to another terminal for communicating a filtered portion of the input signal to another electrical component.

Operation of an ideal BAW resonator would cause the piezoelectric material to operate in an optimum vertical vibration (also called a “piston mode”). However, in practice, operation of a typical, real-world BAW resonator causes propagation of lateral waves (also called “Rayleigh-Lamb modes”), which result in energy being lost by the BAW resonator. Lost energy results in a decrease of a magnitude (or “volume”) of the filtered signal, and thus a decrease in a quality factor of the BAW resonator.

This background provides context for the disclosure. Unless otherwise indicated, material described in this section is not prior art to the claims in this disclosure and is not admitted to be prior art by inclusion in this section.

### SUMMARY

Techniques are disclosed for improving bulk acoustic wave (“BAW”) resonators by providing a lateral energy barrier to reduce energy losses from lateral waves leaking from a resonator. Some of these techniques include providing a reflector outside of the active region and electrically insulated from a top electrode of the resonator.

In an example aspect, a resonator includes a volume of piezoelectric material, a bottom electrode, a top electrode, and a reflector. The volume of piezoelectric material has an upper surface and a lower surface. The bottom electrode is disposed below a portion of the lower surface of the volume of piezoelectric material. The top electrode is disposed above a portion of the upper surface of the volume of piezoelectric material with a portion of the top electrode overlapping a portion of the bottom electrode to define an active region of the volume of piezoelectric material configured to resonate acoustic waves having frequencies within a specified passband. The reflector is disposed outside of the active region with the reflector configured as a lateral energy barrier to reflect laterally propagating acoustic waves having frequencies within the specified passband.

In an example aspect, a resonator includes a volume of piezoelectric material, a bottom electrode, a top electrode, and a reflector. The volume of piezoelectric material has an upper surface and a lower surface. The bottom electrode is disposed below a portion of the lower surface of the volume of piezoelectric material. The top electrode is disposed above a portion of the upper surface of the volume of piezoelectric material with a portion of the top electrode overlapping a portion of the bottom electrode to define an active region of the volume of piezoelectric material configured to resonate acoustic waves having frequencies within a specified passband. The reflector is at least partially embedded in the volume of piezoelectric material outside of the active region with the reflector configured as a lateral energy barrier to reflect laterally propagating acoustic waves having frequencies within the specified passband.

In an example aspect, a resonator includes a volume of piezoelectric material, a bottom electrode, a top electrode, and a reflector. The volume of piezoelectric material has an upper surface and a lower surface. The bottom electrode is disposed below a portion of the lower surface of the volume of piezoelectric material. The top electrode is disposed above a portion of the upper surface of the volume of piezoelectric material with a portion of the top electrode overlapping a portion of the bottom electrode to define an active region of the volume of piezoelectric material configured to resonate acoustic waves having frequencies within a specified passband. The reflector is at least partially surrounding the portion of the top electrode overlapping the portion of the bottom electrode with the reflector configured as a lateral energy barrier to reflect laterally propagating acoustic waves having frequencies within the specified passband.

In another example aspect, a method of forming a bulk acoustic wave (BAW) resonator is provided. The method includes providing a bottom electrode on a portion of a substrate. The method also includes providing a volume of piezoelectric material on an upper surface of the bottom electrode and another portion of the substrate. The method further includes providing a top electrode on a portion of an upper surface of the volume of piezoelectric material with a portion of the top electrode overlapping a portion of the bottom electrode defining an active region of the volume of piezoelectric material that is disposed between the portion of the top electrode and the portion of the bottom electrode. The method additionally includes providing a reflector outside of the active region of the volume of piezoelectric material with the reflector configured as a lateral energy barrier to reflect laterally propagating acoustic waves having frequencies within the specified passband.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

The detailed description is described with reference to the accompanying figures. In the figures, the left-most digit(s) of a reference number identifies the figure in which the reference number first appears. The use of the same reference numbers in different instances in the description and the figures may indicate similar or identical items.

FIG. 1 is an illustration of an example environment for receiving and filtering a wireless signal using a BAW resonator having a lateral energy barrier according to one or more implementations.

FIG. 2 is a schematic view of an example configuration of a BAW resonator having a lateral energy barrier according to one or more implementations.

FIG. 3 is a cross-section view of another example configuration of a BAW resonator having a lateral energy barrier according to one or more implementations.

FIG. 4 is a cross-section view of another example configuration of a BAW resonator having a lateral energy barrier according to one or more implementations.

FIG. 5 is a cross-section view of another example configuration of a BAW resonator having a lateral energy barrier according to one or more implementations.

FIG. 6 is a cross-section view of another example configuration of a BAW resonator having a lateral energy barrier according to one or more implementations.

FIG. 7 is a cross-section view of another example configuration of a BAW resonator having a lateral energy barrier according to one or more implementations.

FIG. 8 is a cross-section view of another example configuration of a BAW resonator having a lateral energy barrier according to one or more implementations.

FIG. 9 is a top view of another example configuration of a BAW resonator having a lateral energy barrier according to one or more implementations.

FIG. 10 is a top view of another example configuration of a BAW resonator having a lateral energy barrier according to one or more implementations.

FIG. 11 is a top view of another example configuration of a BAW resonator having a lateral energy barrier according to one or more implementations.

FIG. 12 is a top view of another example configuration of a BAW resonator having a lateral energy barrier according to one or more implementations.

FIG. 13 is a cross-section view of an example configuration of reflectors and a top electrode of a BAW resonator having a lateral energy barrier according to one or more implementations.

FIG. 14 is a cross-section view of another example configuration of reflectors and a top electrode of a BAW resonator having a lateral energy barrier according to one or more implementations.

FIG. 15 is a cross-section view of another example configuration of reflectors and a top electrode of a BAW resonator having a lateral energy barrier according to one or more implementations.

FIG. 16 is a cross-section view of another example configuration of reflectors and a top electrode of a BAW resonator having a lateral energy barrier according to one or more implementations.

FIG. 17 is a cross-section view of an example system of multiple BAW resonators having a lateral energy barrier according to one or more implementations.

FIG. 18 is schematic view of an example ladder configuration of multiple BAW resonators having a lateral energy barrier according to one or more implementations.

FIG. 19 is a flow diagram that describes operations for forming a BAW resonator according to one or more implementations.

### DETAILED DESCRIPTION

### Overview

Some BAW resonators incur energy losses based on propagation of lateral waves that leak out from the resonator. Certain BAW resonators attempt to reduce losses using frames for mass loading, adding structural steps in the volume of piezoelectric material for redirecting lateral waves back toward the active region of the BAW resonator from an outside region of the BAW resonator, and providing an electrode feed to an outer perimeter of the BAW resonator via an air bridge. However, lateral energy losses continue to persist in these BAW resonators.

This document describes example structures and techniques to decrease lateral energy losses and improve a quality (also called a “Q-factor”) of a BAW resonator. An example resonator structure includes a top electrode and a bottom electrode with a portion of a volume of piezoelectric material forming an active region between an overlap of the top electrode and the bottom electrode. The resonator further includes one or more lateral energy barriers (or “reflectors”) such as a mass load or an acoustic mirror positioned outside of the active region. The one or more lateral energy barriers are electrically insulated from the top electrode to reduce a likelihood of charging the one or more reflectors. This charging may modify an electric field between the bottom electrode and the top electrode and/or generate an acoustic signal from the one or more of the reflectors. Further, the one or more lateral energy barriers may be disposed on an upper surface of the volume of piezoelectric material or may be at least partially embedded in the volume of piezoelectric material.

In the following discussion, an example environment is first described that may employ the apparatuses and techniques described herein. Example apparatuses and configurations are then described, which may be implemented in the example environment as well as other environments. Consequently, example apparatuses and configurations are not limited to the example environment and the example environment is not limited to the example apparatuses and configurations. Further, features described in relation to one example implementation may be combined with features described in relation to one or more other example implementations.

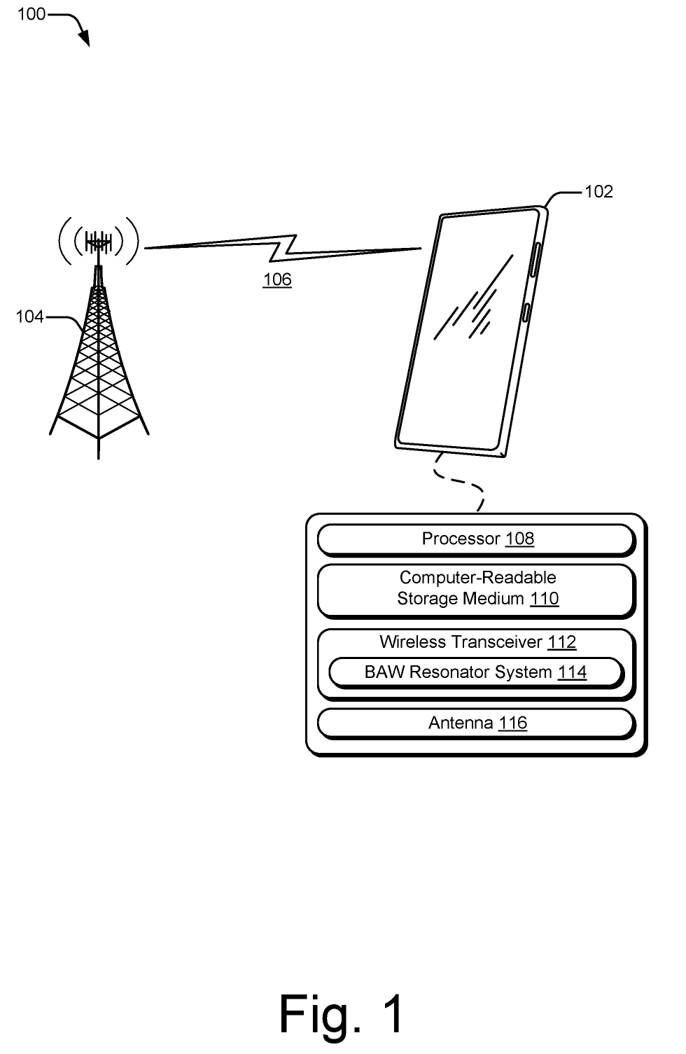

FIG. 1 illustrates an example environment 100, which includes a computing device 102 that communicates with a base station 104 through a wireless communication link 106 (wireless link 106). In this example, the computing device 102 is depicted as a smart phone. However, the computing device 102 may be implemented as any suitable computing or electronic device, such as a modem, cellular base station, broadband router, access point, cellular phone, gaming device, navigation device, media device, laptop computer, desktop computer, tablet computer, server, network-attached storage (NAS) device, smart appliance, vehicle-based communication system, and so forth.

The base station 104 communicates with the computing device 102 via the wireless link 106, which may be implemented as any suitable type of wireless link. Although depicted as a tower of a cellular network, the base station 104 may represent or be implemented as another device, such as a satellite, cable television head-end, terrestrial television broadcast tower, access point, peer-to-peer device, mesh network node, fiber optic line, and so forth. Therefore, the computing device 102 may communicate with the base station 104 or another device via a wired connection, a wireless connection, or a combination thereof.

The wireless link 106 can include a downlink of data or control information communicated from the base station 104 to the computing device 102 and an uplink of other data or control information communicated from the computing device 102 to the base station 104. The wireless link 106 may be implemented using any suitable communication protocol or standard, such as 3rd Generation Partnership Project Long-Term Evolution (3GPP LTE), IEEE 802.11, IEEE 802.16, Bluetooth™, and so forth.

The computing device 102 includes a processor 108 and a computer-readable storage medium 110 (CRM 110). The processor 108 may include any type of processor, such as an application processor or multi-core processor that is configured to execute processor-executable code stored by the CRM 110. The CRM 110 may include any suitable type of data storage media, such as volatile memory (e.g., random access memory (RAM)), non-volatile memory (e.g., Flash memory), optical media, magnetic media (e.g., disk or tape), and so forth. In the context of this disclosure, the CRM 110 is implemented to store instructions, data, and other information of the computing device 102, and thus does not include transitory propagating signals or carrier waves.

A wireless transceiver 112 of the computing device 102 provides connectivity to respective networks and other electronic devices connected therewith. Alternately or additionally, the computing device 102 may include a wired transceiver, such as an Ethernet or fiber optic interface for communicating over a local network, intranet, or the Internet. The wireless transceiver 112 may facilitate communication over any suitable type of wireless network, such as a wireless LAN (WLAN), peer-to-peer (P2P) network, mesh network, cellular network, wireless wide-area-network (WWAN), and/or wireless personal-area-network (WPAN). In the context of the example environment 100, the wireless transceiver 112 enables the computing device 102 to communicate with the base station 104 and networks connected therewith.

The wireless transceiver 112 includes a BAW resonator system 114 configured to filter signals received or to be transmitted via the wireless link 106. The BAW resonator system 114 may be used, for example, as an element of a duplexer for filtering during transmitting and receiving data and/or signals via an antenna 116. In a receiving operation, the antenna 116 receives multiple signals transmitted via one or more wireless networks, such as from the base station 104. The multiple signals can include signals having various frequencies and intended for various devices. The antenna 116 is coupled to the duplexer including the BAW resonator system 114 to perform filtering of the multiple signals. The BAW resonator system 114 may select signals within a specified passband and reject frequencies outside of the passband. The selected signals are then passed, via an output terminal of the BAW resonator system 114, to another component of the computing device 102 for further processing.

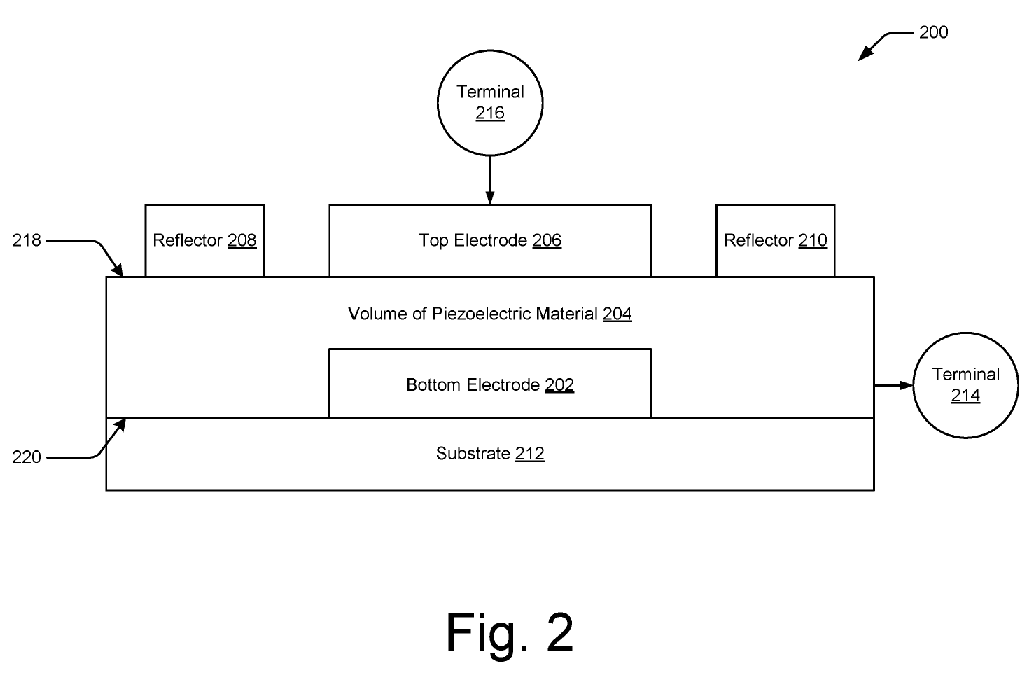

FIG. 2 is a schematic view of an example configuration of a BAW resonator having a lateral energy barrier according to one or more implementations. The configuration includes a resonator 200 of a BAW resonator system 114 for selecting signals within a specified passband. The resonator 200 includes a bottom electrode 202, a volume of piezoelectric material 204, a top electrode 206, reflectors 208 and 210, and a substrate 212. The bottom electrode 202 is coupled to a terminal 214 and the top electrode 206 is coupled to a terminal 216. The bottom electrode 202 is disposed on a portion of the substrate 212 and below a portion of a lower surface 220 of the volume of piezoelectric material 204. The top electrode 206 is disposed above a portion of an upper surface 218 of the volume of piezoelectric material 204. The reflectors 208 and 210 are disposed in an outer region of the volume of piezoelectric material 204 (e.g., outside of an overlap of the top electrode 206 and the bottom electrode 202).

The terminal 216 may be, for example, an input terminal coupled to the antenna 116 for receiving a signal to be filtered by the resonator 200, may be coupled to a signal generator within the computing device 102 for receiving an outbound signal for filtering before transmitting the outbound signal via the wireless link 106, or may be coupled to an output terminal of another filter. The signal is received as an electrical signal at the top electrode 206, which interacts with the volume of piezoelectric material 204 and the bottom electrode 202 to transform the electrical signal into an acoustic signal. The acoustic signal is propagated through the volume of piezoelectric material 204 such that a portion of the acoustic signal propagates vertically (e.g., toward the bottom electrode 202) and a portion of the acoustic signal propagates laterally (e.g., substantially parallel to the upper surface 218 and/or the lower surface 220 of the volume of piezoelectric material 204). An active region of the volume of piezoelectric material 204 (also referred to as an “active region of the resonator”) is defined as a volume of the piezoelectric material 204 between an overlap of the top electrode 206 and the bottom electrode 202. The active region of the resonator 200 is configured to resonate acoustic waves having frequencies within the specified passband.

A portion of the laterally propagating waves of the acoustic signal is reflected toward an active region of the volume of piezoelectric material 204 by the reflector 208 or the reflector 210. The reflected portion of the laterally propagating waves of the acoustic signal includes acoustic waves having frequencies within the specified passband. One or more of the reflectors 208 or 210 may be substantially parallel with an edge of an upper surface of the active region of the volume of piezoelectric material 204 and/or a surface of the active region of the volume of piezoelectric material 204.

In some implementations, one or more of the reflectors 208 or 210 may be curved. A curved reflector 208 or 210 is defined as being substantially parallel with an edge of an upper surface of the active region of the volume of piezoelectric material 204 and/or a surface of the active region of the volume of piezoelectric material 204 if at least a portion of an edge, or a surface, of the reflector 208 or 210 is spaced at a substantially uniform distance from at least a portion of a closest edge of an upper surface of the active region and/or a closest surface of the active region. The distance from the portion of the closest edge of the upper surface of the active region and/or the closest surface of the active region is measured in a direction orthogonal to the closest edge of the upper surface of the active region and/or the closest surface of the active region (see e.g., FIG. 10).

The reflectors 208 and 210 may include conductive material and/or dielectric material. In some implementations, the reflectors 208 and 210 include a same material as the top electrode 206. For example, the reflectors 208 and 210 and the top electrode 206 may include tungsten, titanium, or aluminum copper alloy. In some implementations, the reflectors 208 and 210 have a thermal conductivity coefficient that is greater than that of the volume of piezoelectric material 204 such that the reflectors 208 and 210 provide increased dissipation of thermal energy from the resonator 200.

The bottom electrode 202 transforms a portion of the acoustic signal within the specified passband into a filtered electrical signal. The specified passband is based on resonance of a portion of the acoustic signal within the volume of piezoelectric material 204. The filtered electrical signal is then communicated to the terminal 214 for output. The terminal 214 may communicate the filtered electrical signal from the resonator 200 to the antenna 116 for transmitting the filtered signal from the computing device 102 via the wireless link 106. Alternatively, the terminal 214 may be coupled to a signal processor for further processing of the filtered signal or coupled to an input terminal of another resonator.

In other implementations, the terminal 216 is an output terminal and the terminal 214 is an input terminal. In these implementations, the terminal 214 communicates an electrical signal for filtering at the resonator 200. The electrical signal is transformed into an acoustic signal for propagation through the volume of piezoelectric material 204. A portion of the acoustic signal is transformed into a filtered electrical signal at the top electrode 206 and then communicated to the terminal 216 for output.

The volume of piezoelectric material 204 may be disposed on at least a portion of an upper surface of the bottom electrode 202. The volume of piezoelectric material 204 may include or be formed from, for example, aluminum nitride, quartz crystal, gallium orthophosphate, or lithium-based material, and the like. Furthermore, the volume of piezoelectric material 204 may be doped, sized, and/or cut at various angles to modify propagation, coupling, or other material characteristics.

The resonator 200 may be configured in different manners. For example, the resonator 200 may be configured as a solidly-mounted resonator (“SMR”) including a Bragg mirror between the bottom electrode 202 and the substrate 212. Alternatively, the resonator 200 may be configured as a thin-film bulk acoustic resonator (“FBAR”) having an air gap between the active region of the resonator 200 and the substrate 212.

The upper and lower surfaces are relative. For example, the resonators described herein may be oriented in any direction relative to gravity. Herein, upper surfaces of resonator elements are illustrated nearer the top of the drawing page, and lower surfaces are illustrated nearer the bottom of the drawing page. For example, the upper surface 218 and the lower surface 220 of the volume of piezoelectric material 204 are explicitly indicated in FIG. 2.

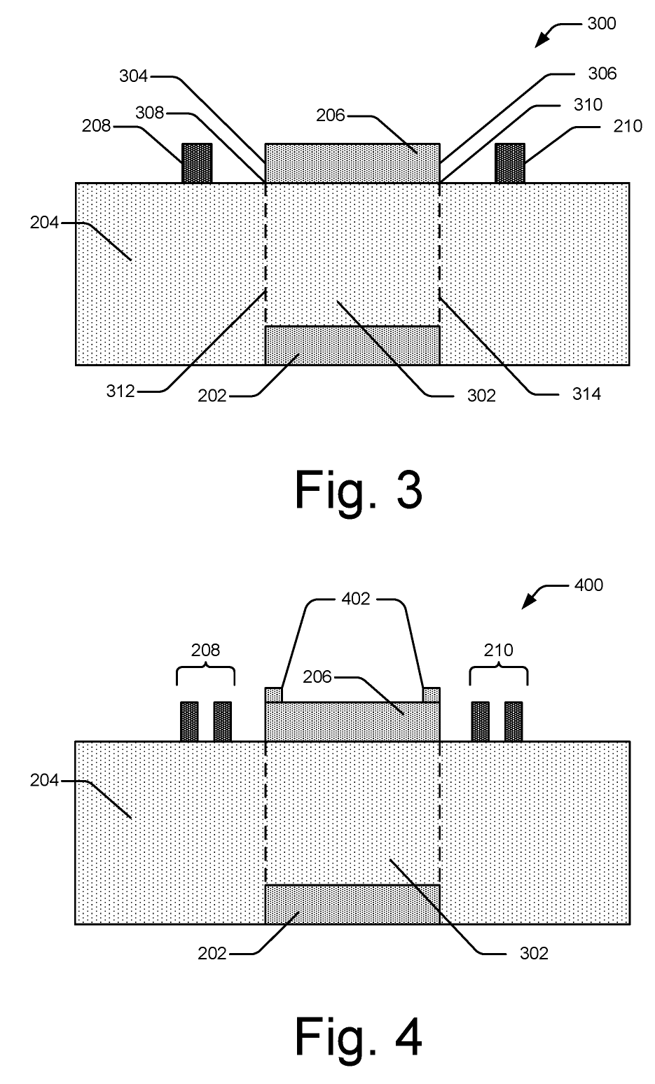

FIG. 3 is a cross-section view of another example configuration of a BAW resonator having a lateral energy barrier according to one or more implementations. A resonator 300 includes elements of the resonator 200 of FIG. 2 including the bottom electrode 202, the volume of piezoelectric material 204, the top electrode 206, and the reflectors 208 and 210. The top electrode 206 includes an edge 304 closest to the reflector 208 and an edge 306 closest to the reflector 210. An active region 302 of the resonator 300 is indicated as a portion of the volume of piezoelectric material 204 disposed between an overlap of the top electrode 206 and the bottom electrode 202. The active region 302 includes an edge 308 of an upper surface of the active region 302 closest to the reflector 208 and an edge 310 of the upper surface of the active region 302 closest to the reflector 210. The active region 302 also includes a boundary 312 closest to the reflector 208 and a boundary 314 closest to the reflector 210.

The reflectors 208 and 210 are positioned on the upper surface of the volume of piezoelectric material 204 and spaced from the top electrode 206. The reflectors 208 and 210 provide a mass-loading effect on portions of the volume of piezoelectric material below them. This causes a step-down in cut-off frequency in these portions, which results in reflection of at least a portion of lateral waves propagating away from the active region 302. In some implementations, a step-up in cut-off frequency may provide increased reflection of lateral waves propagating away from the active region 302. The step-up in cut-off frequency can be realized by removing material, such as a portion of insulating or detuning material, from the upper surface of the volume of piezoelectric material 204.

The reflectors 208 and 210 may be calibrated to reflect acoustic waves having a frequency within the specified passband. For example, the reflector 208 is calibrated by width and/or spacing from the edge 304 of the top electrode 206, the edge 308 of the upper surface of the active region 302, or the boundary 312 of the active region 302 based on wavelengths of acoustic waves having frequencies within the specified passband. Similarly, the reflector 210 may be calibrated by width and/or spacing from the edge 306 of the top electrode 206, the edge 310 of the upper surface of the active region 302, or the boundary 314 of the active region 302 based on wavelengths of acoustic waves having frequencies within the specified passband. In some implementations, the reflectors 208 and 210 have a width (or thickness in a lateral direction) such that:

$$w = n \times \frac{λ}{4} ,$$

where w is a width in a direction orthogonal to a closest edge of the upper surface of the active region, n is a natural number, and λ is a wavelength of a wave within the specified passband. For example, the width is about

$$\frac{λ}{4} .$$

The wavelength λ may represent a shortest wavelength, a longest wavelength, and average wavelength, or a median wavelength of waves having frequencies within the specified passband. The spacing between the reflectors 208 and 210 from the edges 304 and 306, respectively, the edges 308 and 310, respectively, or the surfaces 312 and 314, respectively, may be similarly calibrated to a distance such that

$$d = m \times \frac{λ}{4} ,$$

where d is a distance from one of the reflectors 208 or 210 to a corresponding closest edge of the top electrode 206 (e.g. one of the edges 304 or 306), a corresponding closes edge of the upper surface of the active region 302 (e.g., one or the edges 308 or 310), or a corresponding closest surface of the active region 302 (e.g., one of the surfaces 312 or 314), m is a natural number, and λ is a wavelength of a wave within the specified passband. For example, the distance d is about

$$\frac{λ}{4} .$$

In some implementations, the reflectors 208 and 210 are electrically insulated from the top electrode 206. For example, a volume between the top electrode 206 and each of the reflectors 208 and 210 is filled with a portion of the volume of piezoelectric material 204 or a dielectric such as air or silicon dioxide.

The reflectors 208 and 210 and the top electrode 206 may be formed during a same deposition process during manufacturing. For example, a volume of tungsten is deposited on the upper surface of the volume of piezoelectric material 204. Portions of the volume of tungsten are removed, by processes such as etching, such that the top electrode 206 and the reflectors 208 and 210 remain.

FIG. 4 is a cross-section view of another example configuration of a BAW resonator having a lateral energy barrier according to one or more implementations. A resonator 400 includes elements of the resonator 200 of FIG. 2 including the bottom electrode 202, the volume of piezoelectric material 204, the top electrode 206, and the reflectors 208 and 210. The resonator 400 also illustrates the active region 302 of FIG. 3. The resonator 400 additionally includes a frame 402 for providing a mass-loading effect on one or more portions of the top electrode 206.

The frame 402, similar to the reflectors 208 and 210, causes a step-down in a cut-off frequency of a portion of the volume of piezoelectric material 204 below the frame 402, thus reducing propagation of lateral waves below the frame 402. In some implementations, the frame 402 comprises a same material as the top electrode 206. Additionally or alternatively, the frame 402 may extend along all, or a portion, of an outer perimeter of the top electrode 206. Thus, the frame 402 may be an elliptical ring, a polygon, or an irregular shape, depending on a shape of the outer perimeter of the top electrode 206.

Each of the reflectors 208 and 210 are implemented having multiple reflector elements. The reflector elements are spaced apart (e.g., a volume between them is filled with air or another dielectric) to provide multiple step-ups and step-downs in a cut-off frequency of a portion of the volume of piezoelectric material 204 below the reflectors 208 and 210. This creates multiple interfaces for causing reflection of lateral waves back toward the active region 302. Thus, a reflector having multiple reflector elements may reflect a greater portion of lateral waves back toward the active region 302 and reduce energy lost from leaking lateral waves.

The reflector elements of the reflectors 208 and 210 may be calibrated as described for the reflectors 208 and 210 in reference to FIG. 3. For example, the reflector elements of the reflectors 208 and 210 may be calibrated by width, spacing from each other, and/or spacing from an edge of the top electrode 206, an edge of an upper surface of the active region 302, or a surface of the active region 302 based on wavelengths of acoustic waves having frequencies within the specified passband. Furthermore, one or more of the reflector elements may be substantially parallel to an edge of the top electrode 206, an edge of an upper surface of the active region 302, and/or a surface of the active region 302.

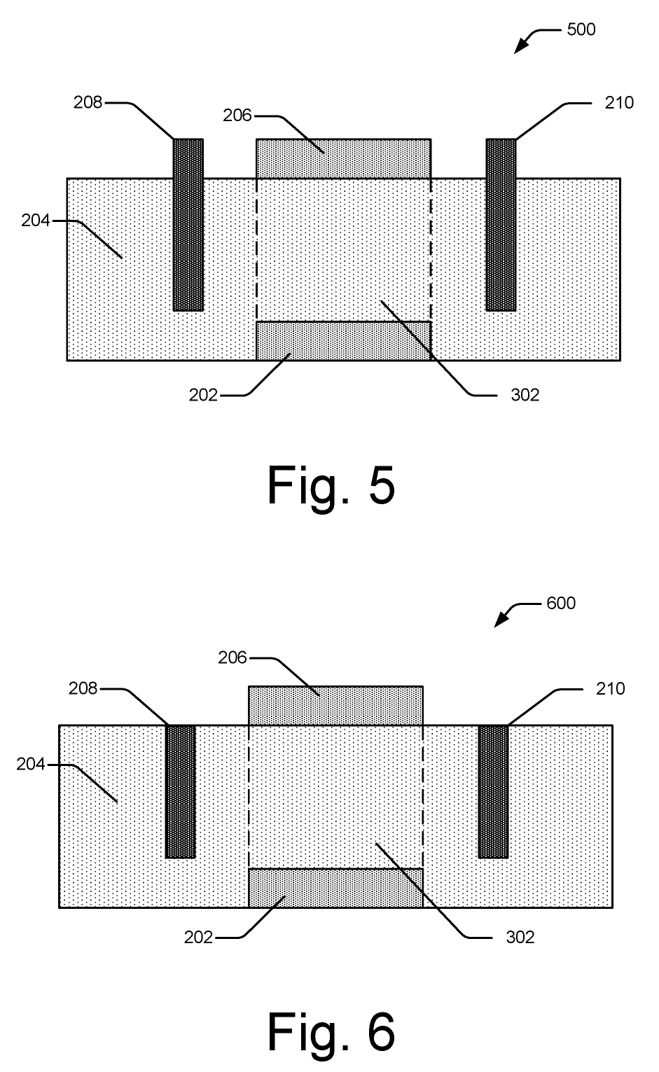

FIG. 5 is a cross-section view of another example configuration of a BAW resonator having a lateral energy barrier according to one or more implementations. A resonator 500 includes elements of the resonator 200 of FIG. 2 including the bottom electrode 202, the volume of piezoelectric material 204, the top electrode 206, and the reflectors 208 and 210. The resonator 500 also illustrates the active region 302 of FIG. 3.

Each of the reflectors 208 and 210 are implemented having a portion embedded in the volume of piezoelectric material 204. The reflectors 208 and 210 may be embedded to a depth in the volume of piezoelectric material 204 such that the reflectors 208 and 210 extend to a depth above, below, or equal to a plane of an upper surface of the bottom electrode 202. In some implementations, one or more of the reflectors 208 or 210 are positioned directly above a portion of the bottom electrode 202. In such implementations, the one or more of the reflectors 208 or 210 may extend to a depth above the plane of the upper surface of the bottom electrode 202 to avoid coupling the one or more of the reflectors 208 or 210 to the bottom electrode 202. This may reduce a likelihood of charging the one or more of the reflectors 208 or 210, which may modify an electric field between the bottom electrode 202 and the top electrode 206 and/or generate an acoustic signal from the one or more of the reflectors 208 or 210.

The reflectors 208 and 210 may include multiple layers alternating between high-impedance material and low-impedance material, with one or more of the multiple layers being oriented vertically and substantially parallel to a closest surface of the top electrode 206, the bottom electrode 202, or the active region 302. For example, a right-most layer of the reflector 208 may include a low-impedance material, adjacent to which, on a left surface of the right-most layer, is a layer of high-impedance material. The multiple layers may alternate along a width of the reflector 208. In this way, the reflector 208 functions as a Bragg mirror to reflect lateral acoustic waves back toward the active region 302 of the resonator 500. The high-impedance materials may include a metal such as tungsten, titanium, gold, or platinum. The low-impedance material may include, for example, a dielectric such as silicone dioxide or a metal such as aluminum, aluminum copper alloy, magnesium, or magnesium alloy.

To embed the reflectors 208 and 210, a portion of the volume of piezoelectric material 204 may be removed using a process such as etching. A volume of space created by removal of the portion of the volume of piezoelectric material 204 may be filled in a single step or, in implementations where the reflectors 208 and 210 include multiple layers, may be filled in in successive steps of deposition and partial removal of materials.

FIG. 6 is a cross-section view of another example configuration of a BAW resonator having a lateral energy barrier according to one or more implementations. A resonator 600 includes elements of the resonator 200 of FIG. 2 including the bottom electrode 202, the volume of piezoelectric material 204, the top electrode 206, and the reflectors 208 and 210. The resonator 600 also illustrates the active region 302 of FIG. 3.

The reflectors 208 and 210 are embedded in the volume of piezoelectric material 204 with upper surfaces substantially coplanar with an upper surface of the volume of piezoelectric material 204. With the reflectors 208 and 210 substantially coplanar with the upper surface of the volume of piezoelectric material 204, another element of the resonator 600 or another material may be disposed on the reflectors 208 and 210 and the upper surface of the volume of piezoelectric material 204 with a substantially coplanar lower surface. Having a substantially coplanar lower surface of an element or material above the reflectors 208 and 210 and the upper surface of the volume of piezoelectric material 204 may facilitate consistency of mass loading on the volume of piezoelectric material 204.

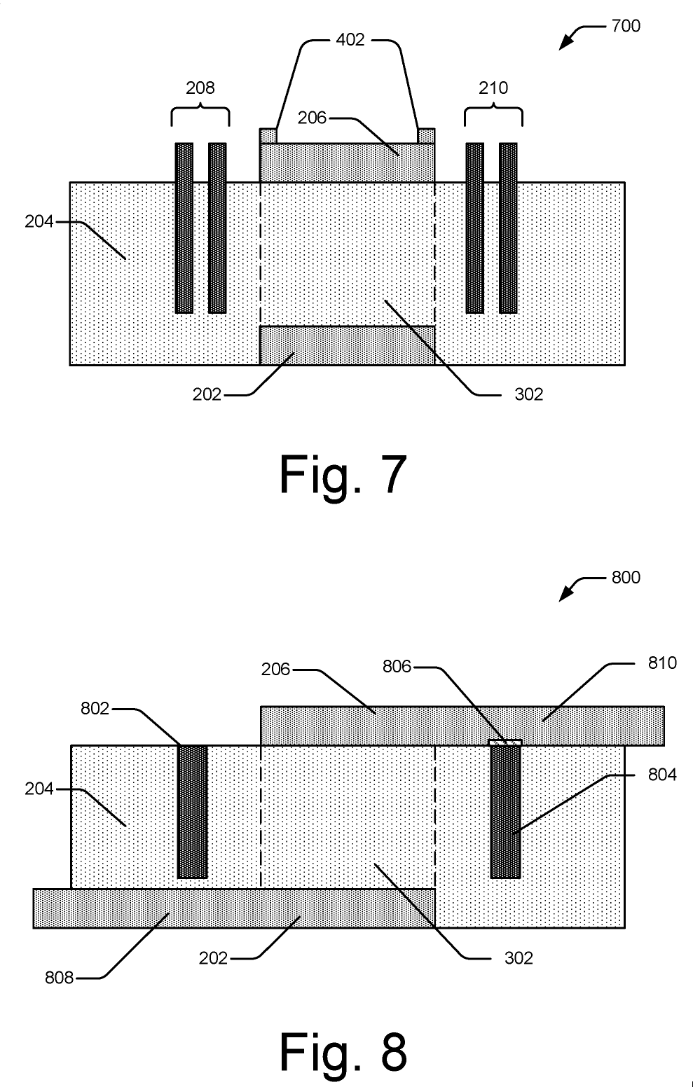

FIG. 7 is a cross-section view of another example configuration of a BAW resonator having a lateral energy barrier according to one or more implementations. A resonator 700 includes elements of the resonator 200 of FIG. 2 including the bottom electrode 202, the volume of piezoelectric material 204, the top electrode 206, and the reflectors 208 and 210. The resonator 700 also illustrates the active region 302 of FIG. 3.

Each of the reflectors 208 and 210 are implemented having multiple reflector elements. The multiple reflector elements of the reflectors 208 and 210 may be calibrated as described for the reflectors 208 and 210 in reference to FIG. 4. For example, the reflector elements of the reflectors 208 and 210 may be calibrated by width, spacing from each other, and/or spacing from an edge of the top electrode 206, an edge of an upper surface of the active region 302, and/or a surface of the active region 302, based on wavelengths of signals within the specified passband. Additionally, each of the reflector elements of the reflectors 208 and 210 includes portions embedded in the volume of piezoelectric material 204.

The reflector elements of the reflectors 208 and 210 may be embedded to a depth in the volume of piezoelectric material 204 such that the reflector elements of the reflectors 208 and 210 extend to a depth above, below, or equal to a plane of an upper surface of the bottom electrode 202. In some implementations, one or more of the reflector elements of the reflectors 208 or 210 are positioned directly above a portion of the bottom electrode 202. In such implementations, the one or more of the reflector elements of the reflectors 208 or 210 may extend to a depth above the plane of the upper surface of the bottom electrode 202 to avoid coupling the one or more of the reflector elements of the reflectors 208 or 210 to the bottom electrode 202. This may reduce a likelihood of charging the one or more of the reflector elements of the reflectors 208 or 210, which may modify an electric field between the bottom electrode 202 and the top electrode 206 and/or cause the one or more of the reflector elements of the reflectors 208 or 210 to generate or couple to an acoustic signal.

Additionally, the reflector elements of the reflectors 208 and 210 may have upper surfaces that are substantially coplanar with the upper surface of the volume of piezoelectric material 204, as discussed with reference to FIG. 6.

FIG. 8 is a cross-section view of another example configuration of a BAW resonator having a lateral energy barrier according to one or more implementations. The cross-section view shown in FIG. 8 is oriented along a length of the bottom electrode 202 and the top electrode 206. The resonator 800 includes elements of the resonator 200 of FIG. 2 including the bottom electrode 202, the volume of piezoelectric material 204, and the top electrode 206. The resonator 800 also illustrates the active region 302 of FIG. 3. Additionally, the resonator 800 includes reflectors 802 and 804, an insulating layer 806, an outer region 808 of the bottom electrode 202 and an outer region 810 of the top electrode 206.

Upper surfaces of the reflectors 802 and 804 are substantially coplanar with the upper surface of the volume of piezoelectric material 204. The reflector 802 is above the outer region 808 of the bottom electrode 202. The reflector 802 extends to a depth above the bottom electrode 202 such that the reflector 802 is electrically insulated from the bottom electrode 202. In some implementations, an insulating layer is disposed between the reflector 802 and the bottom electrode 202. The reflector 804 is below the outer region 810 the top electrode 206. The reflector 804 is substantially parallel to an edge of an upper surface of the active region 302 that borders the outer region 810 of the top electrode 206. The reflector 804 is also substantially parallel to a closest surface of the active region 302. An insulating layer 806 is disposed between the reflector 804 and the outer region 810 to reduce a likelihood of charging the reflector 804 via the top electrode 206. In some implementations, the upper surface of the reflector 804 is below the upper surface of the piezoelectric material 204 such that an upper surface of the insulating layer 806 is substantially coplanar with the upper surface of the volume of piezoelectric material 204.

The outer region 810 of the top electrode 206 extends from an edge of the upper surface of the active region 302 and may couple a portion of the top electrode 206 above the active region 302 to the terminal 216 (not shown). The outer region 808 of the bottom electrode 202 may couple the bottom electrode 202 to the terminal 214. The outer region 810 and the outer region 808 may extend from opposite edges of the upper surface of the active region 302. Alternatively, the outer region 810 and the outer region 808 may extend from adjacent edges of the upper surface of the active region 302.

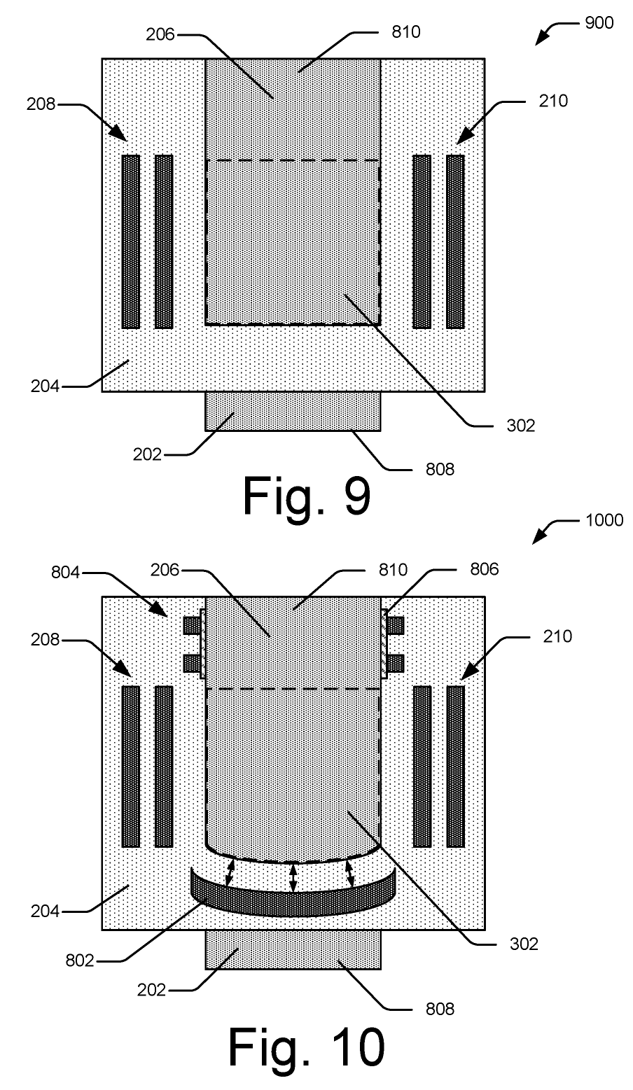

FIG. 9 is a top view of another example configuration of a BAW resonator having a lateral energy barrier according to one or more implementations. A resonator 900 includes elements of the resonator 200 of FIG. 2 including the bottom electrode 202, the volume of piezoelectric material 204, the top electrode 206, and the reflectors 208 and 210. The resonator 900 also illustrates the active region 302 of FIG. 3 and the outer region 808 of the bottom electrode 202 and the outer region 810 of the top electrode 206 of FIG. 8.

The resonator 900 is configured with the reflectors 208 and 210 spaced from, and substantially parallel with, respective closest edges of an upper surface of the active region 302, respective closest edges of the top electrode, and/or respective closest surfaces of the active region 302. The respective closest edges of the upper surface of the active region 302, the respective closest edges of the top electrode, and/or the respective closest surfaces of the active region 302 may be non-adjacent. For example, another edge of the upper surface of the active region 302 (either an upper edge or a lower edge as illustrated) is disposed between an edge that is closest to the reflector 208 and an edge that is closest to the reflector 210. The reflectors 208 and 210 are disposed on an upper surface of, or at least partially embedded in, the piezoelectric material 204 outside of the active region 302. As discussed relative to FIGS. 4 and 7, the reflectors 208 and 210 include multiple reflector elements that are configured to reflect a greater portion of lateral waves back toward the active region 302 and reduce energy lost from leaking lateral waves.

The active region 302 is illustrated having a rectangular cross-section. However, the cross-section of the active region 302 may include a polygon, a partial ellipse, or an irregular shape. In some implementations, an upper surface of the active region 302 is free from parallel edges. A shape of the upper surface of the active region 302 may be based on one or both of the bottom electrode 202 and the top electrode 206. For example, the bottom electrode 202 may include a portion that is a relatively large square and the top electrode 206 may include a portion that is a relatively small circle disposed above, and within a perimeter of, the relatively large square of the top electrode 206. In such implementations, the cross-section of the active region 302 is defined by the relatively small circle of the top electrode 206.

FIG. 10 is a top view of another example configuration of a BAW resonator having a lateral energy barrier according to one or more implementations. A resonator 1000 includes elements of the resonator 200 of FIG. 2 including the bottom electrode 202, the volume of piezoelectric material 204, the top electrode 206, and the reflectors 208 and 210. The resonator 1000 also illustrates the active region 302 of FIG. 3 and the reflector 802, the reflector 804, the insulating layer 806, the outer region 808 of the bottom electrode 202, and the outer region 810 of the top electrode 206 of FIG. 8.

The resonator 1000 is configured with the reflectors 208, 210, 802, and 804 spaced from, and substantially parallel with, respective closest edges of an upper surface of the active region 302, respective closest edges of the top electrode, and/or respective closest surfaces of the active region 302. The reflector 802 is a curved reflector such that at least a portion of an edge, or a surface, of the reflector 802 is spaced at a substantially uniform distance from at least a portion of a closest edge of an upper surface of the active region 302 and/or a closest surface of the active region 302, the distance measured in a direction orthogonal to the closest edge of the upper surface of the active region 302 and/or the closest surface of the active region 302. This provides for a generally uniform distance travelled by laterally propagating acoustic waves from the closest surface of the active region 302 to the reflector 802. Thus, the reflectors 208, 210, 802, and 804 are positioned in a path of a large portion of the lateral waves exiting the active region 302. As discussed relative to FIGS. 4, 7, and 9, the reflectors 208, 210, 802, and 804 include multiple reflector elements that are configured to reflect a greater portion of lateral waves back toward the active region 302 and reduce energy lost from leaking lateral waves.

The insulating layer 806 is disposed between the outer region 810 of the top electrode 206 and the reflector 804 to reduce a likelihood of charging the reflector 804. As discussed relative to FIG. 8, the upper surface of the reflector 804 may below the upper surface of the piezoelectric material 204 such that an upper surface of the insulating layer 806 is substantially coplanar with the upper surface of the volume of piezoelectric material 204. Alternatively, a lower surface of the insulating layer 806 may be substantially coplanar with the upper surface of the volume of piezoelectric material 204.

In some implementations, a quantity of reflectors is equal to a quantity of edges of the surface of the active region 302. In other implementations, a quantity of reflectors is less than a quantity of edges of the upper surface of the active region 302. For example, an alternate implementation of the resonator 1000 may omit the reflector 804 and the insulating layer 806.

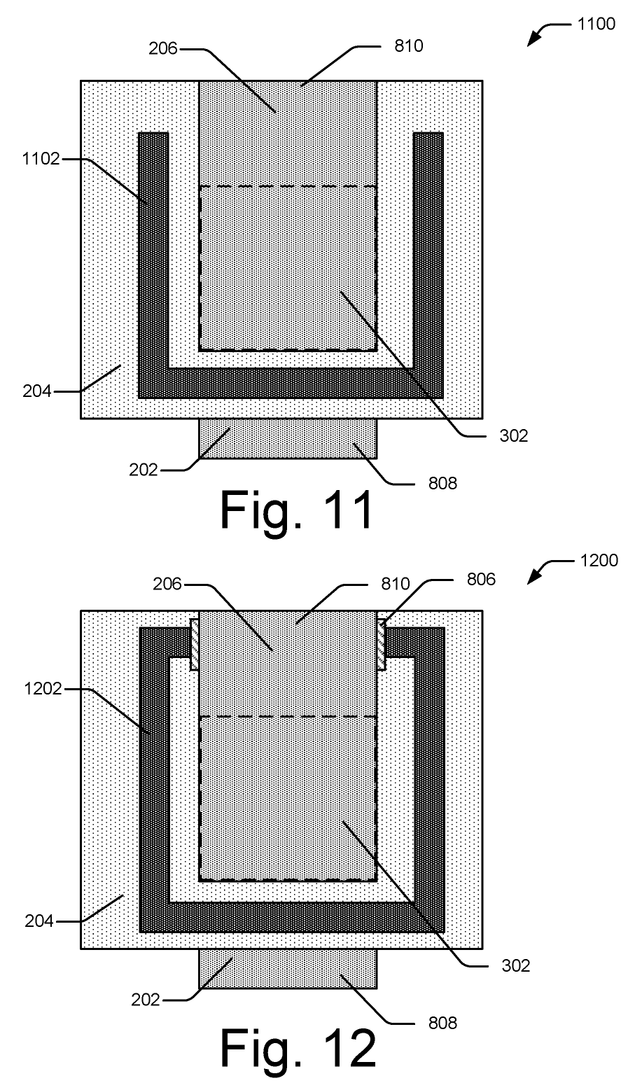

FIG. 11 is a top view of another example configuration of a BAW resonator having a lateral energy barrier according to one or more implementations. The resonator 1100 includes elements of the resonator 200 of FIG. 2 including the bottom electrode 202, the volume of piezoelectric material 204, and the top electrode 206. The resonator 1100 also illustrates the active region 302 of FIG. 3 and the outer region 808 of the bottom electrode 202 and the outer region 810 of the top electrode 206 of FIG. 8. The resonator 1100 also includes a reflector 1102 that partially surrounds a portion of the top electrode 206 in the active region 302.

The reflector 1102 includes multiple segments that are substantially parallel to respective closest edges of an upper surface of the active region 302, respective closest edges of the top electrode, and/or respective closest surfaces of the active region 302. In some implementations, the reflector 1102 includes multiple segments that are substantially parallel to respective closest edges of an upper surface of the active region 302, respective closest edges of the top electrode, and/or respective closest surfaces of the active region 302, excluding an edge of the upper surface of the active region 302 adjacent to the outer region 810 of the top electrode 206. The reflector 1102 may be disposed on an upper surface of the volume of piezoelectric material 204, partially embedded in the volume of piezoelectric material 204, or fully embedded in the volume of piezoelectric material 204. The reflector 1102 may include multiple reflector elements that are configured to reflect a greater portion of lateral waves back toward the active region 302 and reduce energy lost from leaking lateral waves, such as discussed relative to the reflectors 208 and 210 of FIGS. 4, 7, 9, and 10.

FIG. 12 is a top view of another example configuration of a BAW resonator having a lateral energy barrier according to one or more implementations. A resonator 1200 includes elements of the resonator 200 of FIG. 2 including the bottom electrode 202, the volume of piezoelectric material 204, and the top electrode 206. The resonator 1200 also illustrates the active region 302 of FIG. 3 and the outer region 808 of the bottom electrode 202 and the outer region 810 of the top electrode 206 of FIG. 8. The resonator 1200 also includes a reflector 1202 that surrounds a portion of the top electrode 206 in the active region 302. Further, the resonator 1200 includes an insulating layer 806 between the outer region 810 of the top electrode 206 and the reflector 1202.

The reflector 1202 includes multiple segments that are substantially parallel to respective closest edges of an upper surface of the active region 302, respective closest edges of the top electrode, and/or respective closest surfaces of the active region 302. The reflector 1202 may be disposed on an upper surface of the volume of piezoelectric material 204, partially embedded in the volume of piezoelectric material 204, or fully embedded in the volume of piezoelectric material 204. The reflector 1202 may include multiple reflector elements that are configured to reflect a greater portion of lateral waves back toward the active region 302 and reduce energy lost from leaking lateral waves, such as discussed relative to the reflectors 208 and 210 of FIGS. 4, 7, 9, and 10. The multiple reflector elements may be concentric shapes such as circles or rectangle that are similar to a perimeter of the active region 302.

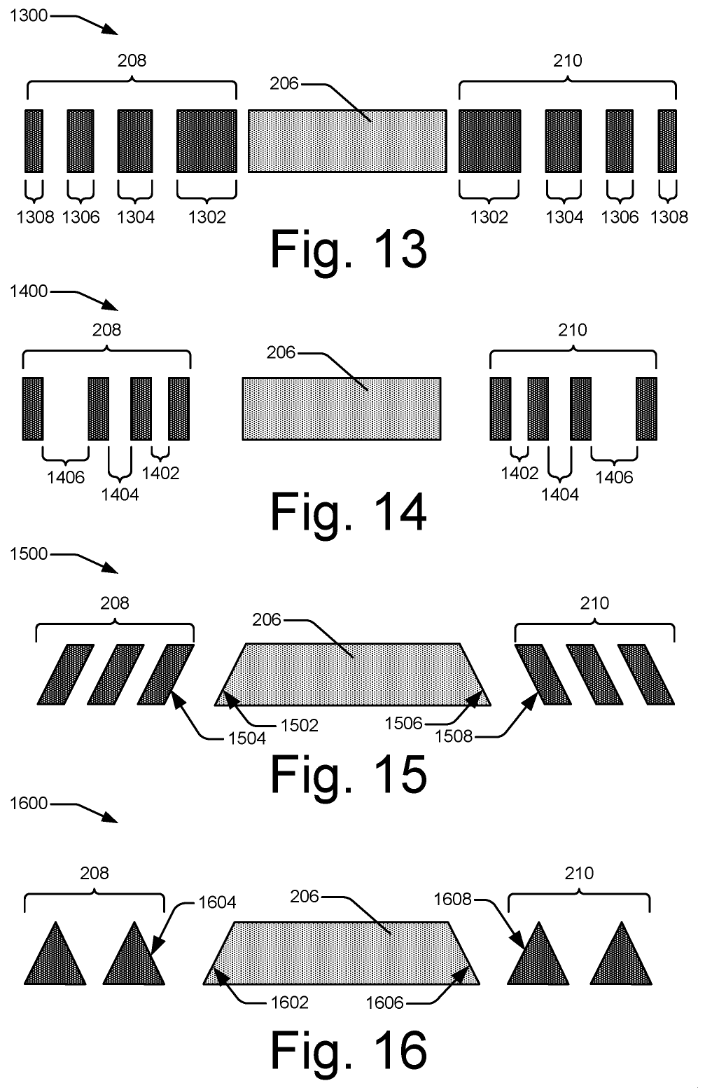

FIG. 13 is a cross-section view of an example configuration of reflectors and a top electrode of a BAW resonator having a lateral energy barrier according to one or more implementations. A resonator 1300 includes elements of the resonator 200 of FIG. 2 including the top electrode 206 and the reflectors 208 and 210. The reflectors 208 and 210 include multiple reflector elements having various widths to reflect a greater portion of lateral waves back toward the active region 302 and reduce energy lost from leaking lateral waves. The various widths can be measured as thicknesses in a direction orthogonal to a closest edge of an upper surface of an active region (not shown) or a closest surface of the active region. The multiple reflector elements may be disposed on an upper surface of the volume of piezoelectric material 204, partially embedded in the volume of piezoelectric material 204, or fully embedded in the volume of piezoelectric material 204. These configurations of the reflectors 208 and 210 may be implemented as, or in combination with, any of the configurations of the reflectors 208 and 210 described herein.

Each of the reflectors 208 and 210 include a first reflector element that is closest to the top electrode 206 having a first width 1302 in a direction orthogonal to an edge of an upper surface of the active region (not shown). The reflectors 208 and 210 each also include a second reflector element having a second width 1304, a third reflector element having a third width 1306, and a fourth reflector element having a fourth width 1308. The widths 1302, 1304, 1306, and 1308 may each be calibrated based on a wavelength of a targeted wave to be reflected. For example, the first width 1302 may be configured such that:

$$w ( 1302 ) = n \times \frac{λ}{4} ,$$

where w is the first width 1302 in the direction orthogonal to the edge of the upper surface of the active region 302, n is a natural number, and λ is a wavelength of a lowest frequency wave within the specified passband when traveling through a material of one of the reflectors 208 or 210. For example, the first width 1302 is about

$$\frac{λ}{4} .$$

The fourth width 1308 may be configured such that:

$$w ( 1308 ) = n \times \frac{α}{4} ,$$

where w is the fourth width 1308, n is a natural number, and α is a wavelength of a highest frequency wave within the specified passband when traveling through a material of one of the reflectors 208 or 210. For example, the fourth width 1308 is about

$$\frac{α}{4} .$$

The widths 1302, 1304, 1306, and 1308 are not required to be ordered by thickness.

FIG. 14 is a cross-section view of another example configuration of reflectors and a top electrode of a BAW resonator having a lateral energy barrier according to one or more implementations. A resonator 1400 includes elements of the resonator 200 of FIG. 2 including the top electrode 206 and the reflectors 208 and 210. Multiple reflector elements of the reflectors 208 and 210 are spaced at various distances to reflect a greater portion of lateral waves back toward the active region 302 and reduce energy lost from leaking lateral waves. The multiple reflector elements may be disposed on an upper surface of the volume of piezoelectric material 204, partially embedded in the volume of piezoelectric material 204, or fully embedded in the volume of piezoelectric material 204. These configurations of the reflectors 208 and 210 may be implemented as, or in combination with, any of the configurations of the reflectors 208 and 210 described herein.

Each of the reflectors 208 and 210 include a first reflector element that is closest to the top electrode 206 that is spaced a first distance 1402 from an adjacent second reflector element. The second reflector element is spaced a second distance 1404 from an adjacent third reflector element, and the third reflector element is spaced a third distance 1406 from an adjacent fourth reflector element. The distances 1402, 1404, and 1406 may each be calibrated based on a wavelength of a targeted wave to be reflected. For example, the first distance 1402 may be configured such that:

$$d ( 1402 ) = n \times \frac{λ}{4} ,$$

where d is the first distance 1402, n is a natural number, and λ is a wavelength of a highest frequency wave within the specified passband when traveling across the first distance 1402. For example, the first distance 1402 is about

$$\frac{λ}{4} .$$

The third distance 1406 may be configured such that:

$$d ( 1406 ) = n \times \frac{α}{4} ,$$

where d is the third distance 1406, n is a natural number, and α is a wavelength of a lowest frequency wave within the specified passband when traveling across the third distance 1406. For example, the third distance 1406 is about

$$\frac{α}{4} .$$

The distances 1402, 1404, and 1406 are not required to be ordered by distance.

FIG. 15 is a cross-section view of another example configuration of reflectors and a top electrode of a BAW resonator having a lateral energy barrier according to one or more implementations. A resonator 1500 includes elements of the resonator 200 of FIG. 2 including the top electrode 206 and the reflectors 208 and 210. Multiple reflector elements of the reflectors 208 and 210 are angled, relative to an upper surface of the volume of piezoelectric material 204 (not shown), to reflect a greater portion of lateral waves back toward the active region 302 and reduce energy lost from leaking lateral waves. The multiple reflector elements may be disposed on an upper surface of the volume of piezoelectric material 204, partially embedded in the volume of piezoelectric material 204, or fully embedded in the volume of piezoelectric material 204. The multiple reflector elements of the reflectors 208 and 210 may be shaped as parallelepipeds extending parallel to an edge of an upper surface of the active region 302 (not shown). These configurations of the reflectors 208 and 210 may be implemented as, or in combination with, any of the configurations of the reflectors 208 and 210 described herein.

The top electrode 206 has a first edge 1502 that is angled such that the first edge 1502 is not orthogonal to a lower surface of the top electrode 206. The reflector 208 includes multiple reflector elements that have an inner (e.g., closest to the top electrode 206) edge 1504 that is angled based on an angle of the first edge 1502. For example, the first edge 1502 and the inner edge 1504 are both angled inward (e.g., an upper portion of the first edge 1502 extends away from the reflector 208 and an upper portion of the inner edge 1504 extends toward the top electrode 206). In some implementations, the first edge 1502 and the inner edge 1504 are substantially parallel.

The top electrode 206 has a second edge 1506 that is angled such that the second edge 1506 is not orthogonal to a lower surface of the top electrode 206. The reflector 210 includes multiple reflector elements that have an inner (e.g., closest to the top electrode 206) edge 1508 that is angled based on an angle of the second edge 1506. For example, the second edge 1506 and the inner edge 1508 are both angled inward (e.g., an upper portion of the second edge 1506 extends away from the reflector 210 and an upper portion of the inner edge 1508 extends toward the top electrode 206). In some implementations, the second edge 1506 and the inner edge 1508 are substantially parallel.

FIG. 16 is a cross-section view of another example configuration of reflectors and a top electrode of a BAW resonator having a lateral energy barrier according to one or more implementations. A resonator 1600 includes elements of the resonator 200 of FIG. 2 including the top electrode 206 and the reflectors 208 and 210. Multiple reflector elements of the reflectors 208 and 210 are angled, relative to an upper surface of the volume of piezoelectric material 204 (not shown), to reflect a greater portion of lateral waves back toward the active region 302 and reduce energy lost from leaking lateral waves. The multiple reflector elements may be disposed on an upper surface of the volume of piezoelectric material 204, partially embedded in the volume of piezoelectric material 204, or fully embedded in the volume of piezoelectric material 204. The multiple reflector elements of the reflectors 208 and 210 may be triangular prisms disposed parallel to an edge of an upper surface of the active region 302 (not shown). These configurations of the reflectors 208 and 210 may be implemented as, or in combination with, any of the configurations of the reflectors 208 and 210 described herein.

The top electrode 206 has a first edge 1602 that is angled such that the first edge 1602 is not orthogonal to an upper surface of the piezoelectric material 204. The reflector 208 includes multiple reflector elements that have an inner (e.g., closest to the top electrode 206) edge 1604 that is angled based on an angle of the first edge 1602. For example, the first edge 1602 is angled inward and the inner edge 1604 is angled outward (e.g., an upper portion of the first edge 1602 extends away from the reflector 208 and an upper portion of the inner edge 1604 extends away from the top electrode 206). In some implementations, the first edge 1602 and the inner edge 1604 are substantially orthogonal.

The top electrode 206 has a second edge 1606 that is angled such that the second edge 1606 is not orthogonal to a lower surface of the top electrode 206. The reflector 210 includes multiple reflector elements that have an inner (e.g., closest to the top electrode 206) edge 1608 that is angled based on an angle of the second edge 1606. For example, the second edge 1606 is angled inward and the inner edge 1608 is angled outward (e.g., an upper portion of the second edge 1606 extends away from the reflector 210 and an upper portion of the inner edge 1608 extends away from the top electrode 206). In some implementations, the second edge 1606 and the inner edge 1608 are substantially orthogonal.

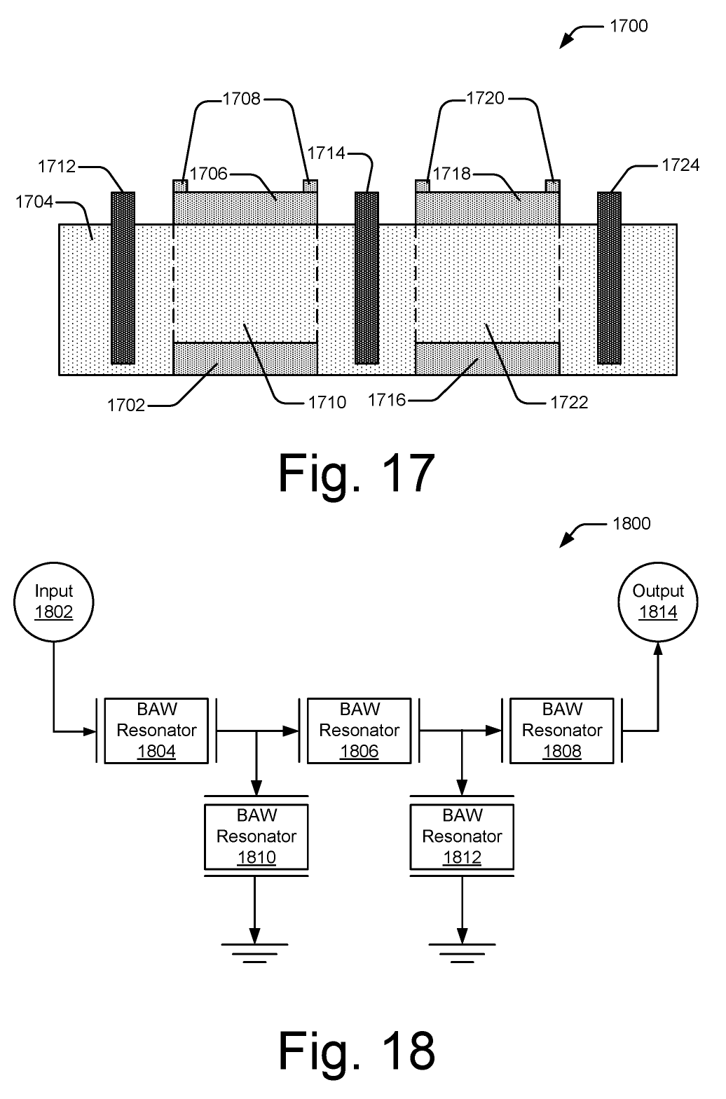

FIG. 17 is a cross-section view of an example system of multiple BAW resonators having a lateral energy barrier according to one or more implementations. A resonator system 1700 includes a first bottom electrode 1702, a volume of piezoelectric material 1704, a first top electrode 1706 having a first frame 1708, and a first active region 1710. A first reflector 1712 is spaced from a first edge of an upper surface of the first active region 1710, a first edge of the first top electrode 1706, and/or a first surface of the first active region 1710. A second reflector 1714 is spaced from a second edge of the upper surface of the first active region 1710, a second edge of the first top electrode 1706, and/or a second surface of the first active region 1710. The resonator system 1700 also includes a second bottom electrode 1716 and a second top electrode 1718 having a frame 1720 forming a second active region 1722. The second reflector 1714 is spaced from a first edge of an upper surface of the second active region 1722, a first edge of the second top electrode 1718, and/or a first surface of the second active region 1722 to reduce leaking of lateral waves propagating from one of the active regions 1710 or 1722 to the other. A third reflector 1724 is spaced a distance from a second edge of the upper surface of the second active region 1722, a second edge of the second top electrode 1718, and/or a second surface of the second active region 1722.

FIG. 18 is a schematic view of an example ladder configuration of multiple BAW resonators having a lateral energy barrier according to one or more implementations. A ladder configuration 1800 may be included in the BAW resonator system 114 for selecting signals within a specified passband. The ladder configuration 1800 includes an input terminal 1802, BAW resonators 1804, 1806, 1808, 1810, and 1812, and an output terminal 1814. One or more of the resonators 1804, 1806, 1808, 1810, or 1812 may be implemented having features described in relation to one or more of the resonators of FIGS. 2-17.

The input terminal 1802 is coupled to the BAW resonator 1804 at an input electrode. The input terminal 1802 may be coupled to the antenna 116 for receiving a signal, or may be coupled to a signal generator within the computing device 102 for transmitting a signal from the computing device 102. After filtering the signal at the BAW resonator 1804, an output electrode of the BAW resonator 1804 is coupled in series to the BAW resonator 1806 at an input electrode of the BAW resonator 1806. After additional filtering of the signal at the BAW resonator 1806, an output electrode of the BAW resonator 1806 is coupled in series to the BAW resonator 1808. After further filtering of the signal at the BAW resonator 1808, an output signal is delivered to an output terminal 1814. The output terminal 1814 may be coupled to the antenna 116 for transmitting the output signal from the computing device 102, or may be coupled to a signal processor for further processing of the output signal.

The output electrode of the BAW resonator 1804 is also coupled to an input electrode of the BAW resonator 1810, which has an output electrode that is coupled to ground, for additional filtering of frequencies outside of the specified passband. Similarly, the output electrode of the BAW resonator 1806 is also coupled to an input electrode of the BAW resonator 1812, which has an output electrode that is coupled to ground, for further filtering of frequencies outside of the specified passband.

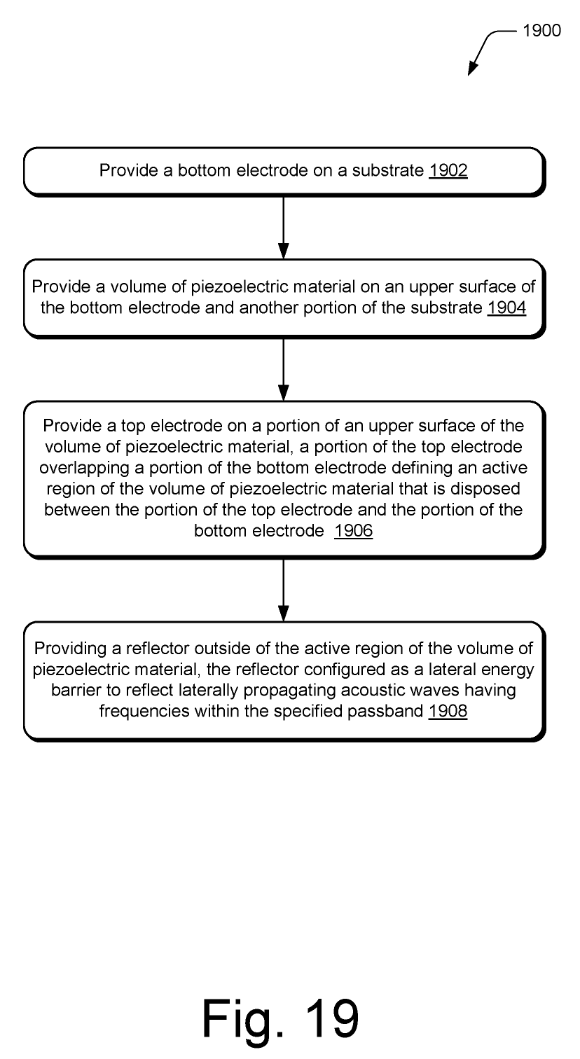

FIG. 19 is a flow diagram that describes operations for forming a BAW resonator according to one or more implementations. A procedure 1900 is shown as a set of blocks that specify operations that are not necessarily limited to the orders shown for performing the operations by the respective blocks. In at least some implementations, the procedure may be performed to form a filter as described in any of FIGS. 2-18.

At operation 1902, a bottom electrode is provided on a substrate. The bottom electrode may be provided using a microelectromechanical systems (“MEMS”) manufacturing process such as deposition and etching. As illustrated in FIG. 2, the bottom electrode 202 is provided on a portion of the substrate 212. At operation 1904, a volume of piezoelectric material is provided on an upper surface of the bottom electrode and another portion of the substrate. The volume of piezoelectric material may be provided through a MEMS manufacturing process as a volume of aluminum nitride. The volume of piezoelectric material may then be planarized to form a substantially planar upper surface. As illustrated in FIGS. 2-8, the volume of piezoelectric material 204 is disposed on an upper surface of the bottom electrode 202 and another portion of the substrate 212.

At operation 1906, a top electrode is provided on a portion of an upper surface of the volume of piezoelectric material. A portion of the top electrode overlaps a portion of the bottom electrode defining an active region of the volume of piezoelectric material that is disposed between the portion of the top electrode and the portion of the bottom electrode. The top electrode may be provided through a MEMS manufacturing process such as deposition and etching. As illustrated in FIGS. 2-12, the top electrode 206 is disposed on a portion of the upper surface 218 of the volume of piezoelectric material 204.

At operation 1908, a reflector is provided outside of the active region of the volume of piezoelectric material with the reflector configured as a lateral energy barrier to reflect laterally propagating acoustic waves having frequencies within the specified passband. The reflector may be provided through a MEMS manufacturing process such as deposition and etching. In some implementations, the reflector and the top electrode are part of a same MEMS manufacturing process. For example, a conductive material may be provided on the upper surface of the volume of piezoelectric material and a portion of the conductive material is removed to define the top electrode and the reflector. The reflector is electrically insulated from the top electrode by, for example, a volume of air between the reflector and the top electrode.

As illustrated in FIGS. 2-12, the reflector 208, 210, 802, 804, 1102, and/or 1202 is provided outside of the active region 302 of the volume of piezoelectric material 204. The reflector may be provide on an upper surface of the volume of piezoelectric material 204, as illustrated in FIGS. 3 and 4, or may be at least partially embedded in the volume of piezoelectric material 204 as shown in FIGS. 5-8.

### Conclusion

Although the implementations of a BAW resonator having a lateral energy barrier have been described in language specific to structural features and/or methodological acts, it is to be understood that the implementations defined in the appended claims are not necessarily limited to the specific features or acts described. Rather, the specific features and acts are disclosed as example forms of implementing the claimed implementations.

What is claimed is:

1. A resonator comprising:
a volume of piezoelectric material having an upper surface and a lower surface;
a bottom electrode disposed below a portion of the lower surface of the volume of piezoelectric material;
a top electrode disposed above a portion of the upper surface of the volume of piezoelectric material, a portion of the top electrode overlapping a portion of the bottom electrode, the overlapping defining an active region of the volume of piezoelectric material, the active region configured to resonate acoustic waves having frequencies within a specified passband; and
a reflector disposed outside of the active region, the reflector configured as a lateral energy barrier to reflect laterally propagating acoustic waves having frequencies within the specified passband.

2. The resonator of claim 1, wherein the reflector is substantially parallel to an edge of an upper surface of the active region.

3. The resonator of claim 1, wherein the reflector includes multiple reflector elements.

4. The resonator of claim 3, wherein at least one reflector element of the multiple reflector elements is sized with a width of about λ/4 in a direction orthogonal to an edge of an upper surface of the active region, wherein λ is a wavelength of an acoustic wave of the laterally propagating acoustic waves having a frequency within the specified passband.

5. The resonator of claim 4, wherein another reflector element of the multiple reflector elements is sized with a width of about α/4 in a direction orthogonal to the edge of the upper surface of the active region, wherein α is another wavelength of another acoustic wave of the laterally propagating acoustic waves having another frequency within the specified passband.

6. The resonator of claim 3, wherein a reflector element of the multiple reflector elements is spaced from another reflector element of the multiple reflector elements at a distance of about λ/4, wherein λ is a wavelength of an acoustic wave of the laterally propagating acoustic waves having a frequency within the specified passband.

7. The resonator of claim 6, wherein the reflector element of the multiple reflector elements is spaced from an additional reflector element of the multiple reflector elements at a distance of about α/4, wherein α is another wavelength of another acoustic wave of the laterally propagating acoustic waves having a frequency within the specified passband.

8. The resonator of claim 3, wherein at least one of the multiple reflector elements is shaped as a triangular prism or a parallelepiped.

9. The resonator of claim 1, wherein the reflector is sized with a width of about λ/4 in a direction orthogonal to an edge of an upper surface of the active region, wherein λ is a wavelength of an acoustic wave of the laterally propagating acoustic waves having a frequency within the specified passband.

10. The resonator of claim 1, wherein the reflector includes a conductive material.

11. The resonator of claim 1, wherein the reflector is electrically insulated from the top electrode.

12. The resonator of claim 1, further comprising another reflector disposed outside of the active region, wherein:
the reflector is spaced from, and substantially parallel with, an edge of an upper surface of the active region;
the other reflector is spaced from, and substantially parallel with, another edge of the upper surface of the active region; and
the edge of the upper surface of the active region and the other edge of the upper surface of the active region are non-adjacent.

13. The resonator of claim 1, further comprising another reflector disposed on the upper surface of the volume of piezoelectric material outside of the active region, wherein:
the reflector is spaced from, and substantially parallel with, a first edge of an upper surface of the active region;
the other reflector is spaced from, and substantially parallel with, a second edge of the upper surface of the active region; and
the top electrode includes an outer region, the outer region of the top electrode extending from a third edge of the upper surface of the active region and coupling the portion of the top electrode to a terminal.

14. The resonator of claim 1, wherein:
the reflector is disposed substantially parallel to an edge of the upper surface of the active region;
an outer region of the top electrode extends from the edge of the upper surface of the active region; and
the resonator further comprises an insulating layer between the reflector and the outer region of the top electrode.

15. The resonator of claim 1, wherein the top electrode includes a frame on a portion of the top electrode.

16. The resonator of claim 1, wherein the reflector is at least partially embedded in the volume of piezoelectric material outside of the active region.

17. The resonator of claim 1, wherein the reflector at least partially surrounds the portion of the top electrode overlapping the portion of the bottom electrode.

18. A resonator comprising:
a volume of piezoelectric material having an upper surface, a lower surface;
a bottom electrode disposed below a portion of the lower surface of the volume of piezoelectric material;
a top electrode disposed above a portion of the upper surface of the volume of piezoelectric material, a portion of the top electrode overlapping a portion of the bottom electrode, the overlapping defining an active region of the volume of piezoelectric material configured to resonate acoustic waves having frequencies within a specified passband; and
a reflector at least partially embedded in the volume of piezoelectric material outside of the active region, the reflector configured as a lateral energy barrier to reflect laterally propagating acoustic waves having frequencies within the specified passband.

19. The resonator of claim 18, wherein the reflector includes multiple layers alternating between high-impedance material and low-impedance material.

20. The resonator of claim 19, wherein the multiple layers are oriented vertically and substantially parallel to a closest surface of the active region.

21. The resonator of claim 18, wherein the reflector is spaced from a surface of the active region at a distance d, where
$$d = m \times \frac{λ}{4} ,$$
m is a natural number, and λ is a wavelength of an acoustic wave of the laterally propagating acoustic waves having frequencies within the specified passband.

22. The resonator of claim 18, wherein the reflector has a width w, where
$$w = n \times \frac{λ}{4} ,$$
n is a natural number, and λ is a wavelength of a wave of the laterally propagating acoustic waves having frequencies within the specified passband.

23. The resonator of claim 18, wherein
the reflector is disposed substantially parallel to an edge of an upper surface of the active region;
an outer region of the top electrode extends from the edge of the upper surface of the active region; and
the resonator further comprises an insulating layer between the reflector and the outer region of the top electrode.

24. A resonator comprising:
a volume of piezoelectric material having an upper surface and a lower surface;
a bottom electrode disposed below a portion of the lower surface of the volume of piezoelectric material;
a top electrode disposed above a portion of the upper surface of the volume of piezoelectric material, a portion of the top electrode overlapping a portion of the bottom electrode, the overlapping defining an active region of the volume of piezoelectric material configured to resonate acoustic waves having frequencies within a specified passband; and
a reflector at least partially surrounding the portion of the top electrode overlapping the portion of the bottom electrode, the reflector configured as a lateral energy barrier to reflect laterally propagating acoustic waves having frequencies within the specified passband.

25. The resonator of claim 24, wherein the reflector includes multiple segments that are substantially parallel to one or more edges of an upper surface of the active region.

26. The resonator of claim 25, wherein the one or more edges of the upper surface of the active region excludes an edge of the active region adjacent to an outer region of the top electrode, the outer region of the top electrode coupling the portion of the top electrode to a terminal.

27. The resonator of claim 24, wherein the reflector is disposed on the upper surface of the volume of piezoelectric material.

28. A method of forming a bulk acoustic wave (BAW) resonator, the method comprising:
providing a bottom electrode on a portion of a substrate;
providing a volume of piezoelectric material on an upper surface of the bottom electrode and another portion of the substrate;
providing a top electrode on a portion of an upper surface of the volume of piezoelectric material, a portion of the top electrode overlapping a portion of the bottom electrode defining an active region of the volume of piezoelectric material that is disposed between the portion of the top electrode and the portion of the bottom electrode; and
providing a reflector outside of the active region of the volume of piezoelectric material, the reflector configured as a lateral energy barrier to reflect laterally propagating acoustic waves having frequencies within a specified passband.

29. The method of claim 28, wherein providing the top electrode and providing the reflector comprise:
providing a conductive material on the upper surface of the volume of piezoelectric material; and
removing a portion of the conductive material to define the top electrode and the reflector, the reflector electrically insulated from the top electrode.

30. The method of claim 28, wherein the reflector is at least partially embedded in the volume of piezoelectric material.
